(19) United States
(12) Patent Application Publication
(10) Pub. No.: US 2015/0249115 A1
(43) Pub. Date: Sep. 3, 2015

(54) ORGANIC ELECTROLUMINESCENCE ARRAY SUBSTRATE, MANUFACTURING METHOD THEREOF AND DISPLAY DEVICE

(71) Applicant: BOE TECHNOLOGY GROUP CO., LTD., Chaoyang District, Beijing (CN)

(72) Inventors: Haijing Chen, Beijing (CN); Jun Cheng, Beijing (CN); Chunsheng Jiang, Beijing (CN); Wulin Shen, Beijing (CN)

(21) Appl. No.: 14/342,219

(22) PCT Filed: Apr. 28, 2013
(86) PCT No.: PCT/CN2013/074954

§ 371 Date: Feb. 28, 2014

(30) Foreign Application Priority Data
Mar. 29, 2013 (CN) 201310109108.X

(51) Int. Cl. H01L 27/32; H01L 51/56

(52) U.S. Cl. CPC H01L 27/3216; H01L 51/56; H01L 27/3218

(57) ABSTRACT

An organic electroluminescence array substrate, a manufacturing method thereof and a display device are provided, and the organic electroluminescence array substrate an active backplane and a color display layer formed on the active backplane, wherein the color display layer includes a plurality of pixel units; and each pixel unit includes a red sub-pixel, a green sub-pixel and a blue sub-pixel. Both an area of the red sub-pixel and an area of the green sub-pixel are less than an area of the blue sub-pixel. The organic electroluminescence array substrate has increased aperture ratio thereof.

### TECHNICAL FIELD

Embodiments of the present invention relate to an organic electroluminescence array substrate, a manufacturing method thereof and a display device.

### BACKGROUND

Compared with liquid crystal displays (LCDs), organic electroluminescence displays are a kind of self-illumination displays with high contrast ratio and wide viewing angle. Organic electroluminescence displays have a plurality of advantages, such as self-illumination, fast response speed, wide viewing angle, and capability of being applied to flexible display, transparent display, three-dimensional (3D) display and the like.

An organic electroluminescence display is generally formed as follows: sub-pixels for emitting red light, green light and blue light respectively are arranged into pixels, and the pixels are in turn arranged to form a matrix and hence form the organic electroluminescence display. The luminous efficiency of organic electroluminescence devices for emitting red light, green light and blue light is different from each other; and the organic electroluminescence devices for emitting red light and green light have higher luminous efficiency but the organic electroluminescence device for emitting blue light has lower luminous efficiency and shorter service life as well. In order to make the display to normally display white light, the three kinds of organic electroluminescence devices must be matched correspondingly: for instance, the electric current supplied to the organic electroluminescence device for emitting blue light may be increased in such a way that the brightness of blue light can be matched with that of red light and green light. However, the increase of the electric current can reduce the service life of the organic electroluminescence devices and hence reduce the service life of the display.

In order to not affect the service life of a display, in the known technology, the effective light-emitting area of an organic electroluminescence device for emitting blue light is often increased in such a way that the brightness of blue light can be matched with that of red light and green light. However, in the design of sub-pixels of the traditional display, both the length and the width of a red sub-pixel, a green sub-pixel and a blue sub-pixel are the same accordingly. In this case, when the effective light-emitting area of the blue sub-pixel is increased, it means that the effective light-emitting areas of the red sub-pixel and the green sub-pixel are each less than that of the blue sub-pixel, and hence the red sub-pixel and the green sub-pixel are certainly provided with regions which do not emit light while do not belong to opaque circuit areas, and consequently the aperture ratio of the red sub-pixel and the green sub-pixel is reduced.

### SUMMARY

Embodiments of the present invention provide an organic electroluminescence array substrate, a manufacturing method thereof and a display device, for which the aperture ratio of the organic electroluminescence array substrate can be increased.

One aspect of the present invention provides an organic electroluminescence array substrate, which comprises an active backplane and a color display layer formed on the active backplane, wherein the color display layer includes a plurality of pixel units; and each pixel unit includes a red sub-pixel, a green sub-pixel and a blue sub-pixel, in which both an area of the red sub-pixel and an area of the green sub-pixel are less than an area of the blue sub-pixel.

For instance, in the above embodiment, the lengths of the red sub-pixel, the green sub-pixel and the blue sub-pixel are the same; and both a width of the red sub-pixel and a width of the green sub-pixel are less than a width of the blue sub-pixel.

For instance, in the embodiment, both an effective light-emitting area of the red sub-pixel and an effective light-emitting area of the green sub-pixel are less than an effective area of the blue sub-pixel.

For instance, in the above embodiment, the effective light-emitting area S_{R} of the red sub-pixel:the effective light-emitting area S_{G} of the green sub-pixel:the effective light-emitting area S_{B} of the blue sub-pixel=R₂R₃:R₁R₃:R₁R₂, in which R₁ indicates luminous efficiency of the red sub-pixel; R₂ indicates luminous efficiency of the green sub-pixel; and R₃ indicates luminous efficiency of the blue sub-pixel.

For instance, in the above embodiment, the width L₁ of the red sub-pixel:the width L₂ of the green sub-pixel:the width L₃ of the blue sub-pixel=(S_{R}+T₁):(S_{G}+T₂):(S_{B}+T₃), in which T₁ indicates an area of a non-luminous region of the red sub-pixel; T₂ indicates an area of a non-luminous region of the green sub-pixel; and T₃ indicates an area of a non-luminous region of the blue sub-pixel.

Another aspect of the present invention further provides a display device, which comprises the foregoing organic electroluminescence array substrate and a package substrate arranged opposite to the array substrate.

Still another aspect of the present invention further provides a method for manufacturing an organic electroluminescence array substrate, which comprises: providing an active backplane; and forming a color display layer on the active backplane, in which the color display layer includes a plurality of pixel units; each pixel unit includes a red sub-pixel, a green sub-pixel and a blue sub-pixel; and both an area of the red sub-pixel and an area of the green sub-pixel are less than an area of the blue sub-pixel.

For instance, in the above embodiment, forming the color display layer on the active backplane further comprises: forming the red sub-pixels, the green sub-pixels and the blue sub-pixels with same lengths and different widths on the active backplane, in which both a width of the red sub-pixel and a width of the green sub-pixel are less than a width of the blue sub-pixel.

For instance, in the above embodiment, forming the red sub-pixels, the green sub-pixels and the blue sub-pixels with same lengths and different widths on the active backplane further comprises: forming the red sub-pixels with the width L1, the green sub-pixels with the width L2 and the blue sub-pixels with the width L3 on the active backplane, wherein L₁:L₂:L₃=(S_{R}+T₁):(S_{G}+T₂):(S_{B}+T₃) and S_{R}:S_{G}:S_{B}=R₂R₃:R₁R₃:R₁R₂, in which S_{R} indicates an effective light-emitting area of the red sub-pixel; S_{G} indicates an effective light-emitting area of the green sub-pixel; S_{B} indicates an effective light-emitting area of the blue sub-pixel; T₁ indicates an area of a non-luminous region of the red sub-pixel; T₂ indicates an area of a non-luminous region of the greens sub-pixel; T₃ indicates an area of a non-luminous region of the blue sub-pixel; R₁ indicates luminous efficiency of the red sub-pixel; R₂ indicates luminous efficiency of the green sub-pixel; and R₃ indicates luminous efficiency of the blue sub-pixel.

### BRIEF DESCRIPTION OF THE DRAWINGS

In order to clearly illustrate the technical solution of the embodiments of the invention, the drawings of the embodiments will be briefly described in the following; it is obvious that the described drawings are only related to some embodiments of the invention and thus are not limitative of the invention.

FIG. 1 is a schematic diagram illustrating the arrangement of an organic electroluminescence array substrate in the traditional display device;

FIG. 2 is a schematic diagram illustrating the arrangement of an organic electroluminescence array substrate in the embodiment of the present invention; and

FIG. 3 is a schematic diagram of a display device in the embodiment of the present invention.

Reference numerals in accompanying drawings:

| | |
|---|---|
| 101 Scanning Line | 102 Data Line |
| 103 Power Line | 104 Opaque Circuit Area |
| 105 Anode of the organic | |
| electroluminescence device | |
| 106 Organic electroluminescence device | 107 Red Sub-pixel |
| 108 Green Sub-pixel | 109 Blue Sub-pixel |

### DETAILED DESCRIPTION

For more clear understanding of the objectives, technical proposals and advantages of the embodiments of the present invention, clear and complete description will be given below to the technical proposals of the embodiments of the present invention with reference to the accompanying drawings of the embodiments of the present invention. It will be obvious to those skilled in the art that the preferred embodiments are only partial embodiments of the present invention but not all the embodiments. All the other embodiments obtained by those skilled in the art without creative efforts on the basis of the embodiments of the present invention illustrated shall fall within the scope of protection of the present invention.

With respect to the problem of low aperture ratio of red sub-pixels and green sub-pixels in a traditional organic electroluminescence display, embodiments of the present invention provide an organic electroluminescence array substrate, a manufacturing method thereof and a display device, in which the aperture ratio of the organic electroluminescence array substrate can be increased.

An embodiment of the present invention provides an organic electroluminescence array substrate, which comprises an active backplane and a color display layer formed on the active backplane, in which the color display layer includes a plurality of pixel units; each pixel unit includes a red sub-pixel, a green sub-pixel and a blue sub-pixel; and both an area of the red sub-pixel and an area of the green sub-pixel are less than an area of the blue sub-pixel.

For instance, lengths of the red sub-pixel, the green sub-pixel and the blue sub-pixel may be the same; and both a width of the red sub-pixel and a width of the green sub-pixel are less than a width of the blue sub-pixel.

As the luminous efficiency of the blue sub-pixel is less than that of the red sub-pixel and that of the green sub-pixel, in order to normally display white light, both the effective light-emitting area of the red sub-pixel and the effective light-emitting area of the green sub-pixel would be less than that of the blue sub-pixel.

For instance, in order to match the effective light-emitting area and the luminous efficiency, the effective light-emitting area S_{R} of the red sub-pixel : the effective light-emitting area S_{G} of the green sub-pixel:the effective light-emitting area S_{B} of the blue sub-pixel=R₂R₃:R₁R₃:R₁R₂, in which R₁ indicates luminous efficiency of the red sub-pixel; R₂ indicates luminous efficiency of the green sub-pixel; and R₃ indicates luminous efficiency of the blue sub-pixel.

Where the lengths of the red sub-pixel, the green sub-pixel and the blue sub-pixel are the same, the width L₁ of the red sub-pixel:the width L₂ of the green sub-pixel:the width L₃ of the blue sub-pixel=(S_{R}+T₁):(S_{G}+T₂):(S_{B}+T₃), in which T₁ indicates an area of a non-luminous region of the red sub-pixel; T₂ indicates an area of a non-luminous region of the green sub-pixel; and T₃ indicates an area of a non-luminous region of the blue sub-pixel.

In the embodiment of the present invention, where the luminous efficiency of the blue sub-pixel is lower, the area of the red sub-pixel and the area of the green sub-pixel are appropriately reduced and the area of the blue sub-pixel is increased, so that the red sub-pixel and the green sub-pixel are not provided with regions which are not utilized, and hence the aperture ratio of the pixel structure can be increased.

An embodiment of the present invention provides a display device, which comprises the foregoing organic electroluminescence array substrate and a package substrate arranged opposite to the array substrate. The display device may be an electronic paper display, a mobile terminal display, a television, an electronic reader or the like.

An embodiment of the present invention further provides a method for manufacturing an organic electroluminescence array substrate, which comprises:

providing an active backplane; and

forming a color display layer on the active backplane, in which the color display layer includes a plurality of pixel units; each pixel unit includes a red sub-pixel, a green sub-pixel and a blue sub-pixel; and both an area of the red sub-pixel and an area of the green sub-pixel are less than an area of the blue sub-pixel.

For instance, the red sub-pixels, the green sub-pixels and the blue sub-pixels with same lengths and different widths may be formed on the active backplane, in which both a width of the red sub-pixel and a width of the green sub-pixel are less than a width of the blue sub-pixel.

When the lengths of the red sub-pixels, the green sub-pixels and the blue sub-pixels are the same, forming the red sub-pixels, the green sub-pixels and the blue sub-pixels on the active backplane further comprises:

forming the red sub-pixels with the width L1, the green sub-pixels with the width L2 and the blue sub-pixels with the width L3 on the active backplane, wherein L₁:L₂:L₃=(S_{R}+T₁):(S_{G}+T₂):(S_{B}+T₃) and S_{R}:S_{G}:S_{B}=R₂R₃:R₁R₃:R₁R₂, in which S_{R} indicates an effective light-emitting area of the red sub-pixel; S_{G} indicates an effective light-emitting area of the green sub-pixel; S_{B} indicates an effective light-emitting area of the blue sub-pixel; T₁ indicates an area of a non-luminous region of the red sub-pixel; T₂ indicates an area of a non-luminous region of the greens sub-pixel; T₃ indicates an area of a non-luminous region of the blue sub-pixel; R₁ indicates luminous efficiency of the red sub-pixel; R₂ indicates luminous efficiency of the green sub-pixel; and R₃ indicates luminous efficiency of the blue sub-pixel.

Detailed description will be given below to the organic electroluminescence array substrate of the present invention with reference to the accompanying drawings and the preferred embodiments.

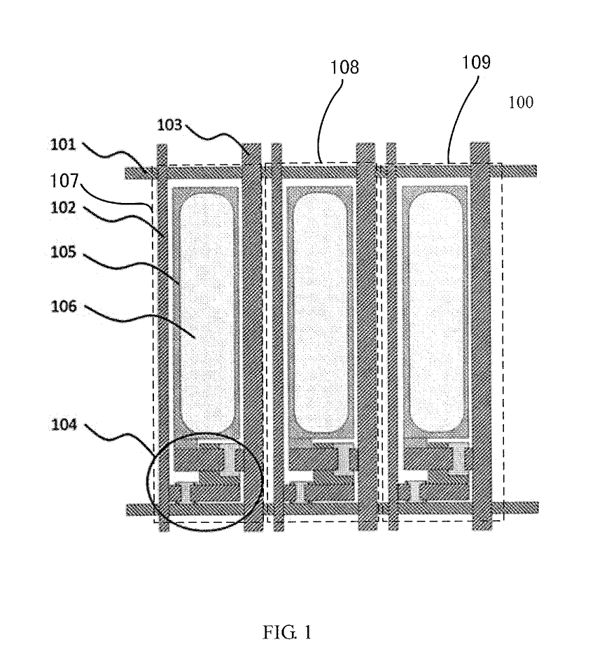

FIG. 1 is a schematic diagram illustrating the arrangement of pixels in an organic electroluminescence device in the traditional display device. As illustrated in FIG. 1, the organic electroluminescence array substrate comprises an active backplane 100, and a plurality of scanning lines 101 parallel to each other, a plurality of data lines 102 parallel to each other and a plurality of power lines 103 are formed on the active backplane. The scanning lines 101 and the data lines 102 are perpendicular to each other to define sub-pixel regions; the defined sub-pixel regions include red sub-pixels 107, green sub-pixels 108 and blue sub-pixels 109. These three types of sub-pixels are adjacently and repeatedly arranged in the order of red, green and blue; and the red sub-pixel 107, the green sub-pixel 108 and the blue sub-pixel 109 which are adjacent to each other are arranged to form a pixel unit. Each sub-pixel includes an organic electroluminescence device 106; and correspondingly, the red sub-pixel, the green sub-pixel and the blue sub-pixel are respectively provided with luminescent devices capable of emitting red light, green light and blue light. Moreover, each sub-pixel further includes a driving transistor, a switching transistor and a capacitor, in which a drain electrode of the driving transistor is electrically connected with the power line 103; a source electrode of the driving transistor is electrically connected with an anode 105 of the organic electroluminescence device; a gate electrode of the driving transistor is electrically connected with a drain electrode of the switching transistor; one end of the capacitor is electrically connected with the gate electrode of the driving transistor and the other end of the capacitor is electrically connected with the source electrode of the driving transistor. A gate electrode of the switching transistor is electrically connected with the scanning line; and a source electrode of the switching transistor is electrically connected with the data line.

As illustrated in FIG. 1, in the traditional sub-pixel design, both the width and the length of the red sub-pixels, the green sub-pixels and the blue sub-pixels are the same, and the areas of opaque circuit regions 104 in the three types of sub-pixels are basically the same as well. As the luminous efficiency of the blue sub-pixel is less than that of the red sub-pixel and that of the green sub-pixel, in order to normally display white light, the effective light-emitting area of the blue sub-pixel would be greater than that of the red sub-pixel and that of the green sub-pixel. In the case where the red sub-pixel, the green sub-pixel and the blue sub-pixel have different effective light-emitting areas, the sub-pixel design is limited by the blue sub-pixel with the greatest effective light-emitting area, and hence the red sub-pixel and the green sub-pixel are certainly provided with regions which do not emit light and do not belong to opaque circuit areas, and consequently the aperture ratio of the red sub-pixel and the green sub-pixel is reduced.

In order to solve the above-mentioned problem, in an embodiment of the present invention, the ratio of the effective light-emitting area of various sub-pixels is obtained at first according to the matching conditions of red light, green light and blue light and the factors such as luminous efficiency, service life and the like of organic electroluminescence devices for emitting red light, green light and blue light respectively. The ratio of the effective light-emitting area of the red sub-pixel, the green sub-pixel and the blue sub-pixel can be obtained by the following formula:

S_{R}:S_{G}:S_{B}=R₂R₃:R₁_{R}₃:R₁R₂,

in which R₁ indicates luminous efficiency of the red sub-pixel; R₂ indicates luminous efficiency of the green sub-pixel; and R₃ indicates luminous efficiency of the blue sub-pixel.

After the ratio of the effective light-emitting areas of the red sub-pixel, the green sub-pixel and the blue sub-pixel is obtained, the dimension of the red sub-pixel and the green sub-pixel can be appropriately reduced and the dimension of the blue sub-pixel can be increased by the adjustment upon the areas of the red sub-pixel, the green sub-pixel and the blue sub-pixel according to the ratio.

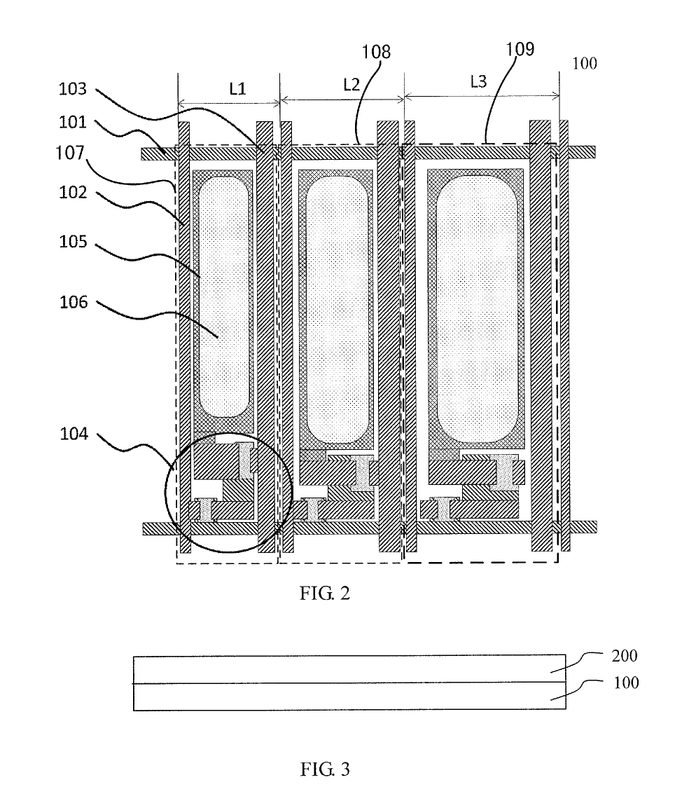

FIG. 2 is a schematic diagram illustrating the pixel arrangement of an organic electroluminescence device in the embodiment of the present invention. As illustrated in FIG. 2, the organic electroluminescence array substrate comprises an active backplane 100, wherein a plurality of scanning lines 101 parallel to each other, a plurality of data lines 102 parallel to each other and a plurality of power lines 103 are formed on the active backplane; the scanning lines 101 and the data lines 102 are perpendicular to each other to define sub-pixel regions; the defined sub-pixel regions include red sub-pixels 107, green sub-pixels 108 and blue sub-pixels 109; these three types of sub-pixels are adjacently and repeatedly arranged in the order of red, green and blue; and the red sub-pixel 107, the green sub-pixel 108 and the blue sub-pixel 109 which are adjacent to each other are arranged to form a pixel unit. The present invention is not limited to the arrangement modes of the red, green and blue sub-pixels in the pixel unit.

Each sub-pixel includes an organic electroluminescence device 106. Correspondingly, the red sub-pixel, the green sub-pixel and the blue sub-pixel are respectively provided with luminescent devices capable of emitting red light, green light and blue light respectively. Moreover, each sub-pixel at least further includes a driving transistor, a switching transistor and a capacitor, in which a drain electrode of the driving transistor is electrically connected with the power line 103; a source electrode of the driving transistor is electrically connected with an anode 105 of the organic electroluminescence device; a gate electrode of the driving transistor is electrically connected with a drain electrode of the switching transistor; one end of the capacitor is electrically connected with the gate electrode of the driving transistor and the other end of the capacitor is electrically connected with the source electrode of the driving transistor; a gate electrode of the switching transistor is electrically connected with the scanning line; and a source electrode of the switching transistor is electrically connected with the data line.

As illustrated in FIG. 2, when the red sub-pixel, the green sub-pixel and the blue sub-pixel are arranged side by side, both the length and the width of a pixel unit are represented by L; the widths of the red sub-pixel, the green sub-pixel and the blue sub-pixel of the pixel unit are respectively represented by L₁, L₂ and L₃; the area of a non-luminous region of the red sub-pixel is represented by T₁; the area of a non-luminous region of the green sub-pixel is represented by T₂; the area of a non-luminous region of the blue sub-pixel is represented by T₃; and hence the ratio of the red sub-pixel width to the green sub-pixel width to the blue sub-pixel width, namely L₁:L₂:L₃, can be obtained by the following formula: L₁:L₂:L₃=(S_{R}+T₁):(S_{G}+T₂):(S_{B}+T₃).

As the luminous efficiency of the blue sub-pixel is less than that of the red sub-pixel and that of the green sub-pixel, in order to normally display white light, the effective light-emitting area of the blue sub-pixel must be greater than that of the red sub-pixel and that of the green sub-pixel. In the embodiment of the present invention, where the luminous efficiency of the blue sub-pixel is lower, the areas of the red sub-pixel and the green sub-pixel are reduced and the area of the blue sub-pixel is increased according to the ratio of the luminous efficiency, so that the red sub-pixel and the green sub-pixel are not provided with regions which are not utilized, and hence the aperture ratio of a pixel structure can be increased.

An embodiment of the present invention provides a display device. As illustrated in FIG. 3, the display device comprises an organic electroluminescence array substrate 100 and a package substrate 200 arranged opposite to the array substrate 100. The package substrate 200 covers a surface of the array substrate 100 in such a way that the array substrate 100 is isolated from outside moisture and oxygen, and hence the service life of the display device can be prolonged.

The foregoing is only the preferred embodiments of the present invention and not intended to limit the scope of protection of the present invention. The scope of protection of the present invention should be defined by the appended claims.

1. An organic electroluminescence array substrate, comprising an active backplane and a color display layer formed on the active backplane, wherein the color display layer includes a plurality of pixel units; and each pixel unit includes a red sub-pixel, a green sub-pixel and a blue sub-pixel, in which both an area of the red sub-pixel and an area of the green sub-pixel are less than an area of the blue sub-pixel.

2. The organic electroluminescence array substrate according to claim 1, wherein lengths of the red sub-pixel, the green sub-pixel and the blue sub-pixel are the same; and both a width of the red sub-pixel and a width of the green sub-pixel are less than a width of the blue sub-pixel.

3. The organic electroluminescence array substrate according to claim 2, wherein both an effective light-emitting area of the red sub-pixel and an effective light-emitting area of the green sub-pixel are less than an effective area of the blue sub-pixel.

4. The organic electroluminescence array substrate according to claim 3, wherein the effective light-emitting area S_{R} of the red sub-pixel:the effective light-emitting area S_{G} of the green sub-pixel:the effective light-emitting area S_{B} of the blue sub-pixel=R₂R₃:R₁R₃:R₁R₂, in which R₁ indicates luminous efficiency of the red sub-pixel; R₂ indicates luminous efficiency of the green sub-pixel; and R₃ indicates luminous efficiency of the blue sub-pixel.

5. The organic electroluminescence array substrate according to claim 4, wherein the width L₁ of the red sub-pixel:the width L₂ of the green sub-pixel:the width L₃ of the blue sub-pixel=(S_{R}+T₁):(S_{G}+T₂):(S_{B}+T₃), in which T₁ indicates an area of a non-luminous region of the red sub-pixel; T₂ indicates an area of a non-luminous region of the green sub-pixel; and T₃ indicates an area of a non-luminous region of the blue sub-pixel.

6. A display device, comprising an organic electroluminescence array substrate and a package substrate arranged opposite to the array substrate, wherein the organic electroluminescence array substrate comprises:
an active backplane and a color display layer formed on the active backplane, wherein the color display layer includes a plurality of pixel units; and each pixel unit includes a red sub-pixel, a green sub-pixel and a blue sub-pixel, in which both an area of the red sub-pixel and an area of the green sub-pixel are less than an area of the blue sub-pixel.

7. A method for manufacturing an organic electroluminescence array substrate, comprising:
providing an active backplane; and
forming a color display layer on the active backplane, wherein the color display layer includes a plurality of pixel units; each pixel unit includes a red sub-pixel, a green sub-pixel and a blue sub-pixel; and both an area of the red sub-pixel and an area of the green sub-pixel are less than an area of the blue sub-pixel.

8. The method for manufacturing the organic electroluminescence array substrate according to claim 7, wherein forming the color display layer on the active backplane further comprises:
forming the red sub-pixels, the green sub-pixels and the blue sub-pixels with same lengths and different widths on the active backplane, in which both the width of the red sub-pixel and the width of the green sub-pixel are less than the width of the blue sub-pixel.

9. The method for manufacturing the organic electroluminescence array substrate according to claim 8, wherein forming the red sub-pixels, the green sub-pixels and the blue sub-pixels with same lengths and different widths on the active backplane further comprises:
forming the red sub-pixels with the width L1, the green sub-pixels with the width L2 and the blue sub-pixels with the width L3 on the active backplane, wherein L₁:L₂:L₃=(S_{R}+T₁):(S_{G}+T₂):(S_{B}+T₃) and S_{R}:S_{G}:S_{B}=R₂R₃:R₁R₃:R₁R₂,
in which S_{R} indicates an effective light-emitting area of the red sub-pixel; S_{G} indicates an effective light-emitting area of the green sub-pixel; S_{B} indicates an effective light-emitting area of the blue sub-pixel; T₁ indicates an area of a non-luminous region of the red sub-pixel; T₂ indicates an area of a non-luminous region of the greens sub-pixel; T₃ indicates an area of a non-luminous region of the blue sub-pixel; R₁ indicates luminous efficiency of the red sub-pixel; R₂ indicates luminous efficiency of the green sub-pixel; and R₃ indicates luminous efficiency of the blue sub-pixel.

10. The display device according to claim 6, wherein lengths of the red sub-pixel, the green sub-pixel and the blue sub-pixel are the same; and both a width of the red sub-pixel and a width of the green sub-pixel are less than a width of the blue sub-pixel.

11. The display device according to claim 10, wherein both an effective light-emitting area of the red sub-pixel and an effective light-emitting area of the green sub-pixel are less than an effective area of the blue sub-pixel.

12. The display device according to claim 11, wherein the effective light-emitting area S_{R} of the red sub-pixel the effective light-emitting area S_{G} of the green sub-pixel:the effective light-emitting area S_{B} of the blue sub-pixel=R₂R₃:R₁R₃:R₁R₂, in which R₁ indicates luminous efficiency of the red sub-pixel; R₂ indicates luminous efficiency of the green sub-pixel; and R₃ indicates luminous efficiency of the blue sub-pixel.

13. The display device according to claim 12, wherein the width L₁ of the red sub-pixel:the width L₂ of the green sub-pixel the width L₃ of the blue sub-pixel=(S_{R}+T₁):(S_{G}+T₂):(S_{B}+T₃), in which T₁ indicates an area of a non-luminous region of the red sub-pixel; T₂ indicates an area of a non-luminous region of the green sub-pixel; and T₃ indicates an area of a non-luminous region of the blue sub-pixel.
